(19) United States
(12) Patent Application Publication
(10) Pub. No.: US 2024/0026561 A1
(43) Pub. Date: Jan. 25, 2024

(54) PLATING APPARATUS AND PLATING METHOD

(71) Applicant: ACM RESEARCH (SHANGHAI), INC., Shanghai (CN)

(72) Inventors: Zhaowei Jia, Shanghai (CN); Jian Wang, Shanghai (CN); Hui Wang, Shanghai (CN); Hongchao Yang, Shanghai (CN)

(73) Assignee: ACM RESEARCH (SHANGHAI), INC., Shanghai (CN)

(21) Appl. No.: 18/254,783

(22) PCT Filed: Oct. 29, 2021
(86) PCT No.: PCT/CN2021/127543

§ 371 Date: May 26, 2023

(30) Foreign Application Priority Data
Nov. 26, 2020 (CN) 202011348069.5

(51) Int. Cl. C25D 21/12; C25D 17/10; C25D 17/00; C25D 7/12; H01L 21/288

(52) U.S. Cl. CPC C25D 21/12; C25D 17/10; C25D 17/001; C25D 17/002; C25D 7/12; H01L 21/2885

(57) ABSTRACT

The present invention discloses a plating apparatus. The plating apparatus comprises a multiple electrodes. The multiple electrodes include a main electrode and at least two second electrodes. The main electrode and the at least two second electrodes respectively generate an electric field in a corresponding area on the surface of a wafer. The main electrode and the at least two second electrodes respectively have a control interface. By selecting the combination of the control relationship between each second electrode and the main electrode, the wafers with different sizes or different notch shapes are plated, and the control relationship is independent control or joint control. The plating apparatus of the present invention can plate wafers with different sizes or different notch shapes without replacing the whole plating chamber.

### BACKGROUND OF THE INVENTION

### 1. Field of the Invention

The present invention generally relates to semiconductor devices manufacturing, and more particularly relates to a plating apparatus and a plating method.

### 2. The Related Art

In the field of semiconductor devices manufacturing, an electroplating process generally uses wafers as substrates to be plated and, metal layers or metal wires are formed in designated areas of the substrates by employing the electroplating process to achieve specific circuit functions. In addition, in the advanced packaging process, electroplating is also adopted to form copper pillars and solder bumps so as to realize interconnections between chips and the substrate.

In a cup-type plating apparatus, the wafer as a cathode is horizontally arranged on a chuck, and a soluble or insoluble anode is arranged below the wafer. During electroplating, the wafer is immersed in electrolyte and metal ions in the electrolyte are deposited on the surface of the wafer under the effect of an electric field.

When the wafer containing a non-plated area (known as a notch area) is being holistically plated, since the photoresist on the non-plated area has no openings, so there is no metal deposition at the non-plated area, leading to electric current being more concentrated at a plated area around the non-plated area, so that the plating height at the plated area around the non-plated area is higher than that of other area, which will cause product yield reduction. So a prior patent application (CN 110512248 A) mentioned a plating apparatus with multiple electrodes, every electrode forming an independent electric field, and when the notch of the wafer rotates to a designated area, the independent electric field corresponding to the designated area could be changed, so a total amount of power received by the non-plated area within the designated area is reduced to lower the plating height of the non-plated area of the wafer.

Besides, the current density on the entire wafer is not uniform due to “terminal effect”, which causes a higher plating rate at the edge of the wafer and a lower plating rate at the center of the wafer, resulting in uneven plating film. A diffusion plate with a lot of through-holes is arranged between the anode and the cathode, and the diameters of the through-holes gradually decrease from the center to the edge of the wafer. Such design of the diffusion plate strengthens the flowing of the electrolyte and the electric field in the central area of the wafer, making the height of the plated metal on the entire wafer more uniform.

Corresponding to wafers with different sizes or with different notch shapes, the position of electrodes also needs to be changed, and then the design of the whole plating chamber needs to be modified, which will undoubtedly increase much cost.

### SUMMARY OF THE INVENTION

An object of the present invention is to achieve plating on wafers with different sizes or different notch shapes without replacing the whole plating chamber.

In order to achieve the above object, the present invention discloses a plating apparatus comprising multiple electrodes. The multiple electrodes include a main electrode and at least two second electrodes. The main electrode and the at least two second electrodes respectively generate an electric field in a corresponding area on the surface of a wafer. The main electrode and the at least two second electrodes respectively have a control interface. By selecting the combination of the control relationship between each second electrode and the main electrode, wafers with different sizes or different notch shapes are plated, and the control relationship is independent control or joint control.

According to an embodiment, when the second electrode and the main electrode are controlled independently, the electric field intensity generated by the second electrode in the corresponding area is different from the electric field intensity generated by the main electrode in the corresponding area, when the second electrode and the main electrode are controlled jointly, the electric field intensity generated by the second electrode in the corresponding area is the same with the electric field intensity generated by the main electrode in the corresponding area.

According to an embodiment, the control interfaces are power interfaces. The main electrode is connected to a main power supply, and each second electrode is selectively connected to a second power supply or the main power supply.

According to an embodiment, the main electrode is corresponding to the central area of the wafer, and the electric field generated by each second electrode doesn't overlap with each other.

According to an embodiment, the number of the second electrodes is two, and the angle between the axis of one second electrode and the axis of the other second electrode is 180°.

According to an embodiment, each second electrode is corresponding to a notch area of the wafer. The distance between the center of the main electrode and the second electrode corresponding to the notch of a wafer with a larger size is a longer distance, and the distance between the center of the main electrode and the second electrode corresponding to the notch of a wafer with a smaller size is a shorter distance. The longer distance is larger than the shorter distance.

According to an embodiment, each second electrode is set in a first bounding wall and the first bounding wall is used to separate the electric field generated by the second electrode with the electric field generated by the main electrode.

According to an embodiment, the plating apparatus further comprises an ionic membrane set on an ionic membrane frame. The ionic membrane is used to separate a cathode area from an anode area in a plating chamber, and the end of the first bounding wall is connected to the ionic membrane.

According to an embodiment, in order to better control the height of the plating metal on the wafer, a diffusion plate with a perforations-area matching with the size of the wafer to be plated is set between the ionic membrane and the wafer. Multiple perforations are set in the perforations-area. A second bounding wall is set between the ionic membrane and the diffusion plate, and the two ends of the second bounding wall are respectively connected to the ionic membrane frame and the diffusion plate. The shape and location of the second bounding wall match with the shape and location of the first bounding wall.

According to an embodiment, in order to better control the height of the plating metal near the notch area on the wafer, a main diffusion plate with a main perforations-area is set between the ionic membrane and the wafer. At least one notch area is set in the main perforations-area. The shape and location ofthe at least one notch area match with at least one second electrode. A second bounding wall is set on the ionic membrane frame. The shape and location of the second bounding wall match with the shape and location of the first bounding wall. A second diffusion plate with a second perforations-area is set on an end of the second bounding wall. Multiple perforations are respectively set in the main perforations-area and the second perforations-area. After the main diffusion plate is mounted, the second diffusion plate is correspondingly mounted at the notch area of the main diffusion plate, and the main perforations-area of the main diffusion plate and the second perforations-area of the second diffusion plate join together to form a complete circle.

According to an embodiment, the main diffusion plate and the second diffusion plate are mounted detachably.

According to an embodiment, a baffle plate is detachably mounted between the diffusion plate and the wafer, and the baffle plate is employed to cover the periphery annular region of the perforations-area in order to fit for the plating of wafers with different sizes.

According to an embodiment, the density of the perforations in the second perforations-area is smaller than the density of the perforations in the main perforations-area, and/or the diameter of the perforations in the second perforations-area is smaller than the diameter of the perforations in the main perforations-area.

The present invention discloses a plating method. The plating method comprises: plating on the surface of a wafer with a plating apparatus having electrodes, wherein the electrodes include a main electrode and at least two second electrodes; controlling the main electrode and the at least two second electrodes to generate an electric field in the corresponding area on the surface of the wafer, each second electrode and the main electrode being controlled independently or controlled jointly, by changing the combination of the control relationship between each second electrode and the main electrode, wafers with different sizes or different notch shapes being plated.

According to an embodiment, further comprising connecting the main electrode to a main power supply and selectively connecting each second electrode to a second power supply or the main power supply so that the independent control or joint control between each second electrode and the main electrode is realized.

According to an embodiment, further comprising connecting the main electrode to a main rectifier and selectively connecting the second electrode to the main rectifier or a second rectifier so that the independent control or joint control between each second electrode and the main electrode is realized.

The present invention can realize plating on wafers with different sizes or different notch shapes without replacing the whole plating chamber, so that the cost of the plating apparatus is reduced, and the height of the plating metal on the wafer is effectively controlled.

### BRIEF DESCRIPTION OF THE DRAWINGS

FIG. 1 illustrates a top view of a plating apparatus according to a first embodiment of the present invention;

FIG. 2 illustrates a cross-sectional view of a plating apparatus according to a second embodiment of the present invention;

FIG. 3 illustrates a cross-sectional view of a plating apparatus according to a third embodiment of the present invention;

FIG. 4 illustrates a cross-sectional view of a plating apparatus without a baffle plate according to a fourth embodiment of the present invention;

FIG. 5 illustrates a cross-sectional view of the plating apparatus with a baffle plate according to the fourth embodiment of the present invention;

FIG. 6 illustrates a cross-sectional view of a plating apparatus according to a fifth embodiment of the present invention;

FIG. 7 illustrates a cross-sectional view of a plating apparatus with second diffusion plates according to a sixth embodiment of the present invention;

FIG. 8 illustrates the shapes of the second diffusion plates of the sixth embodiment of the present invention;

FIG. 9A and FIG. 9B illustrate the shapes of two types of main diffusion plate of the plating apparatus according to the sixth embodiment of the present invention;

FIG. 10 illustrates a cross-sectional view of the plating apparatus with a baffle plate according to the sixth embodiment of the present invention;

FIG. 11A and FIG. 11B illustrate circuit diagrams of the plating apparatus of the first embodiment of the present invention while two different wafers are plated by employing the plating apparatus; and

FIG. 12 illustrates a circuit diagram of a plating apparatus according to a seventh embodiment of the present invention.

### DETAILED DESCRIPTION OF EMBODIMENTS

Hereinafter, the subject matter described herein will be discussed with reference to a plurality of embodiments. It should be understood that discussion of these embodiments is to enable a person of normal skill in the art to better understand and thereby implement the subject matter described herein, not implying any limitation to the scope of the subject matter described herein.

The plating apparatus disclosed by the embodiments of the present invention comprises a main electrode and at least two second electrodes, and each electrode forms an electric field in the corresponding area of the surface of the wafer. Each electrode respectively has a control interface. By selecting the combination mode of controlling relationship between each second electrode and the main electrode, the electroplating on wafers with different sizes or with different shapes of notches is realized. Said controlling relationship is independent control or joint control. Said control interface may be a power interface used to be connected to a power supply, and said control interface may also be a switch interface used to be connected to multi-way switch circuits.

The following are the embodiments of the plating apparatus of the present invention.

### Embodiment 1

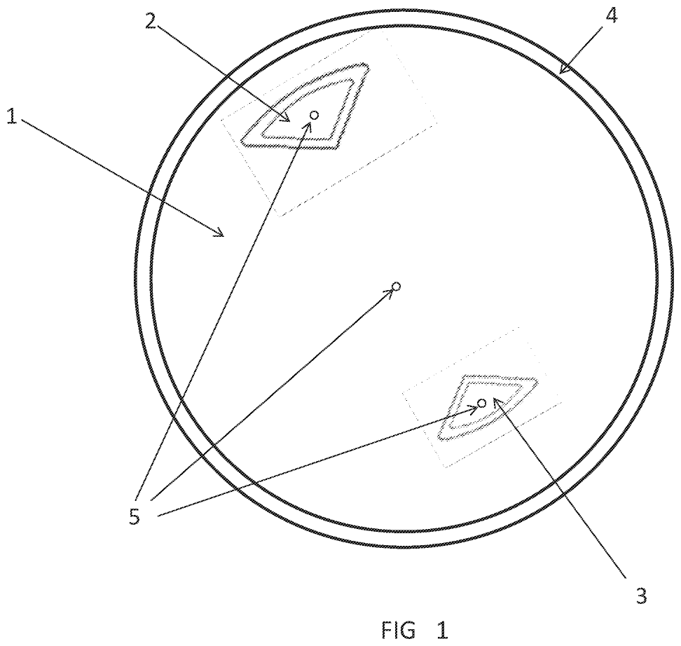

Please refer to FIG. 1 illustrating a top view of a plating apparatus. The plating apparatus comprises a plating chamber 4. An anode area is positioned at the bottom of the plating chamber 4, and there are three electrodes in the anode area. Specifically, the three electrodes are respectively located in a main anode area 1, a second anode area 2 for a 12-inch wafer and a second anode area 3 for an 8-inch wafer.

There is a through hole 5 in the main anode area 1, which is used to connect the main electrode in the main anode area 1 to the positive pole of a main power supply. There are two through holes 5, one of which is set in one second anode area and the other of which is set in the other second anode area, respectively used to connect the second electrode in the second anode area 2 for a 12-inch wafer and the second electrode in the second anode area 3 for an 8-inch wafer to the positive pole of the main power supply or the positive pole of a second power supply, and the connecting way is chosen based on the wafer size in practical plating. As a power interface, the through holes 5 can be used to connect each electrode to various types of power supply, such as PWM switch power supply and linear power supply, etc.

The shape and location of the second anode area 3 for an 8-inch wafer is corresponding to the shape and location of the notch of the 8-inch wafer, and the shape and location of the second anode area 2 for a 12-inch wafer is corresponding to the shape and location of the notch of the 12-inch wafer, and the nearest distance between the second anode area 2 for a 12-inch wafer and the center of the plating chamber 4 is larger than the farthest distance between the second anode area 3 for an 8-inch wafer and the center of the plating chamber 4, that is to say, the area covered by the 8-inch wafer doesn't overlap with the area covered by the notch of the 12-inch wafer. The main anode area 1 is a circle with two notches where the second anode area 2 for a 12-inch wafer and the second anode area 3 for an 8-inch wafer are positioned. The center of the main anode area 1 is opposite to the center of the wafer to be plated, and the distance between the second anode area 3 for an 8-inch wafer and the center of the main anode area 1 is smaller than the distance between the second anode area 2 for a 12-inch wafer and the center of the main anode area 1.

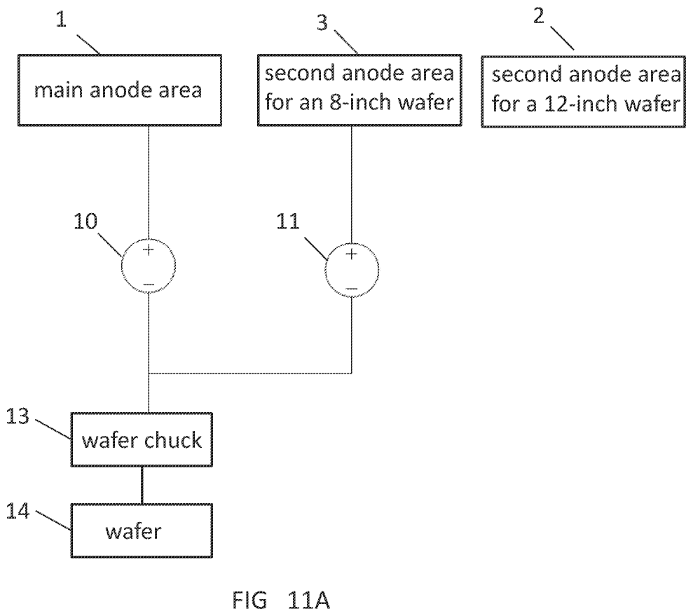

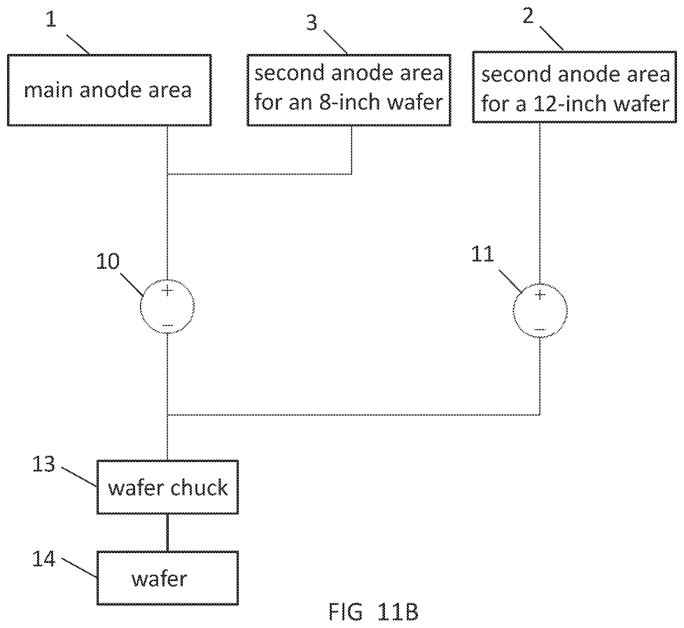

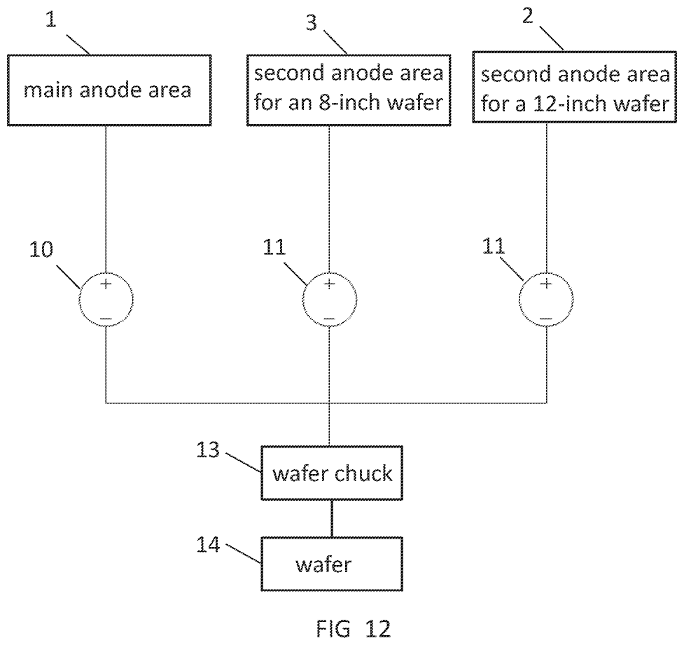

Referring to FIG. 11A, for the 8-inch wafer plating, the positive pole of the second power supply 11 is connected to the second electrode in the second anode area 3 for an 8-inch wafer, while the second electrode in the second anode area 2 for a 12-inch wafer is not connected to any power supply. The positive pole of the main power supply 10 is connected to the main electrode in the main anode area 1. Referring to FIG. 11B, for the 12-inch wafer plating, connect the second electrode in the second anode area 3 for an 8-inch wafer with the main electrode in the main anode area 1 in parallel, and then connect to the positive pole of the main power supply 10, and the second electrode in the second anode area 2 for a 12-inch wafer is connected to the positive pole of the second power supply 11. In FIG. 11A, FIG. 1B and FIG. 12, both the negative pole of the main power supply 10 and the negative pole of the second power supply 11 are connected to the wafer 14 via a wafer chuck 13 which is used for holding and positioning the wafer 14 while the wafer 14 is plated.

Specifically, in an 8-inch wafer plating process, the second anode area 2 for a 12-inch wafer doesn't overlap with the 8-inch wafer, so the second electrode in the second anode area 2 for a 12-inch wafer doesn't work and doesn't generate an electric filed. Because the second electrode in the second anode area 3 for an 8-inch wafer and the main electrode in the main anode area 1 are respectively connected to an independent power supply, the electric field intensity generated by them can be controlled separately, so when a notch of the 8-inch wafer is positioned within the designated area, a total amount of power received by the notch within the designated area can be controlled, so that the height of the plating metal near the notch of the 8-inch wafer is in accordance with other area.

In a 12-inch wafer plating process, the notch of the 12-inch wafer doesn't overlap with the 8-inch wafer, and the second anode area 3 for an 8-inch wafer is located in the area covered by the 12-inch wafer, so the second electrode in the second anode area 3 for an 8-inch wafer and the main electrode in the main anode area 1 need to be controlled together, and both of them are connected to the positive pole of the main power supply 10 so that the electric fields generated by them have a same intensity. The second electrode in the second anode area 2 for a 12-inch wafer is connected to the positive pole of the second power supply 11, so it generates an electric field whose intensity is different from the electric field generated by the main anode area 1 and the second anode area 3 for an 8-inch wafer.

In order to reduce the interaction between the second anode area 2 for a 12-inch wafer and the second anode area 3 for an 8-inch wafer, it is preferable to keep them as far away as possible, and it is preferable that the angle between the symmetry axes of them is 180°.

### Embodiment 2

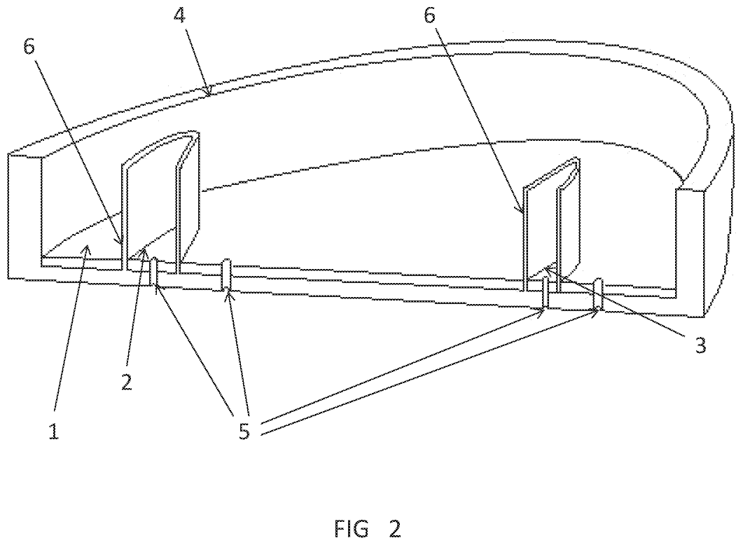

Please refer to FIG. 2, what is different with the first embodiment is that in the second embodiment, there are multiple through holes 5 in the main anode area 1. In plating process, each through hole 5 is connected to the positive pole of the main power supply to raise the uniformity of the electric field. Each second electrode is respectively located in a first bounding wall 6, and the first bounding wall 6 is used to separate the electric field generated by the second electrode with the electric field generated by the main electrode, so that the height of plating metal near the notch of the wafer is effectively controlled.

The other parts in the second embodiment are the same with the first embodiment.

### Embodiment 3

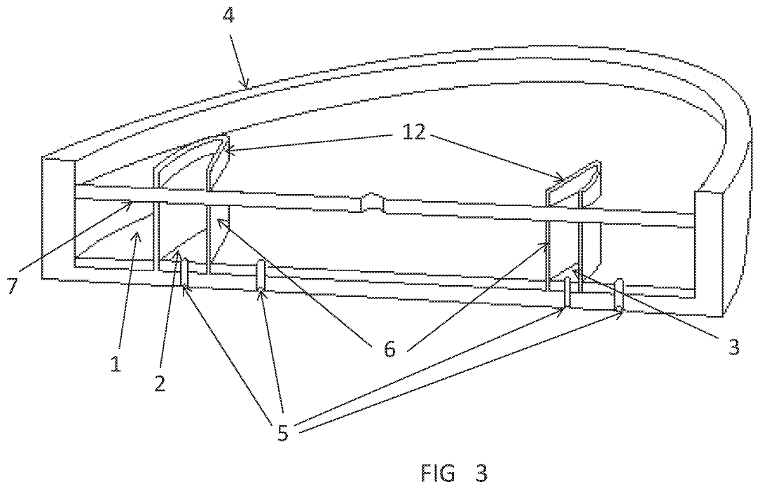

Referring to FIG. 3, the plating apparatus in the third embodiment includes all the components of the plating apparatus in the second embodiment, which will not be repeated here.

What's more, there is an ionic membrane 7 above the anode area, and the ionic membrane 7 is set on an ionic membrane frame, and the ionic membrane 7 separates the cathode area from the anode area in the plating chamber 4. The cathode area is above the ionic membrane 7 while the anode area is underneath the ionic membrane 7. The function of the ionic membrane 7 is to allow the desired metal ion in the anode area to pass through in order to supplement the concentration of the desired metal ion in the cathode area, and to prevent the additive molecule from reaching the anode area. The end of the first bounding walls 6 connect with the ionic membrane 7. There are two second bounding walls 12 in the cathode area, and the two second bounding walls 12 match with the two first bounding walls 6 in the anode area respectively to separate the flow field and the electric field. The end of the second bounding walls 12 connect with the ionic membrane frame.

### Embodiment 4

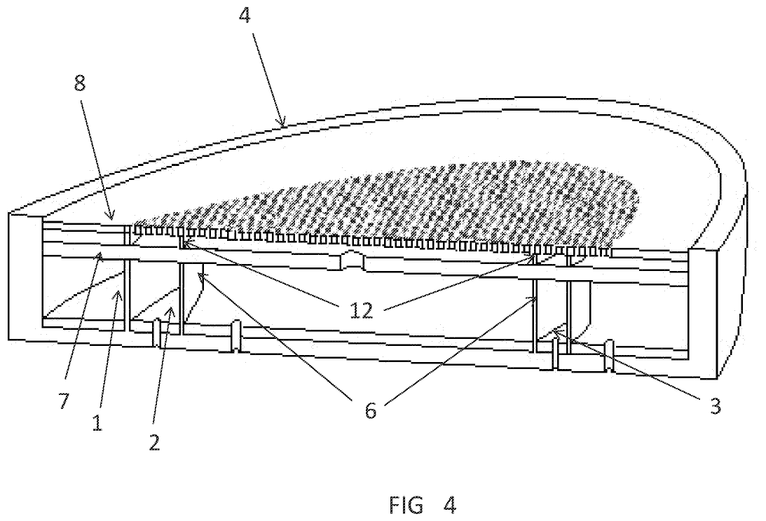

Referring to FIG. 4, the plating apparatus in the fourth embodiment includes all the components of the plating apparatus in the third embodiment, which will not be repeated here.

What's more, a diffusion plate 8 is set in the cathode area of the plating chamber 4, and the diffusion plate 8 is connected to the end of the second bounding walls 12. There are several perforations with the same size or different sizes on the diffusion plate 8 to control the flow field and electric field in the plating process. The desired metal ions pass through the ionic membrane 7 and the diffusion plate 8 and reach the wafer then deposit on it.

In FIG. 4, the diffusion plate 8 is fixed on the plating chamber 4, and the electric field generated by the area with perforations can cover the entire wafer to be plated with the maximum size such as a 12-inch wafer.

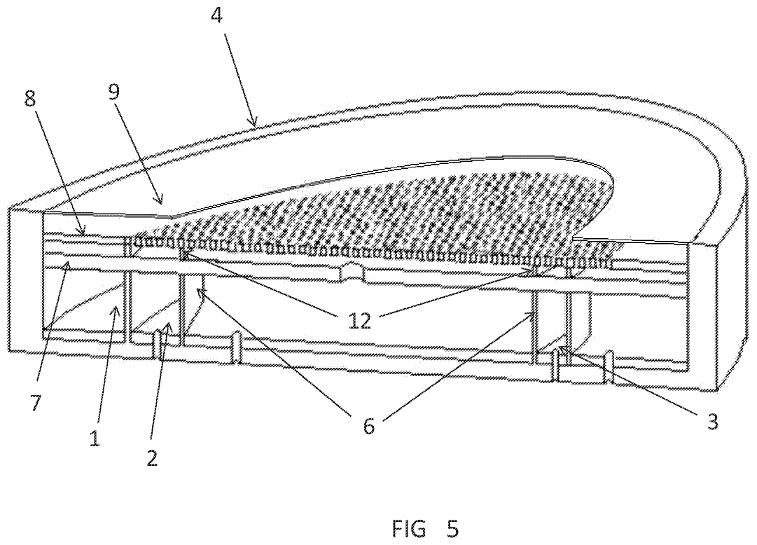

Referring to FIG. 5, if a wafer with a smaller size such as 8 inch needs to be plated, a baffle plate 9 is employed to cover the periphery annular region of the diffusion plate 8, so that only the central area of the diffusion plate 8 is exposed to fit for the plating of the wafer with a smaller size such as 8 inch, and the cathode liquid in the periphery annular region of the diffusion plate 8 is blocked by the baffle plate 9. The baffle plate 9 is detachably mounted on the plating chamber 4 or the diffusion plate 8.

### Embodiment 5

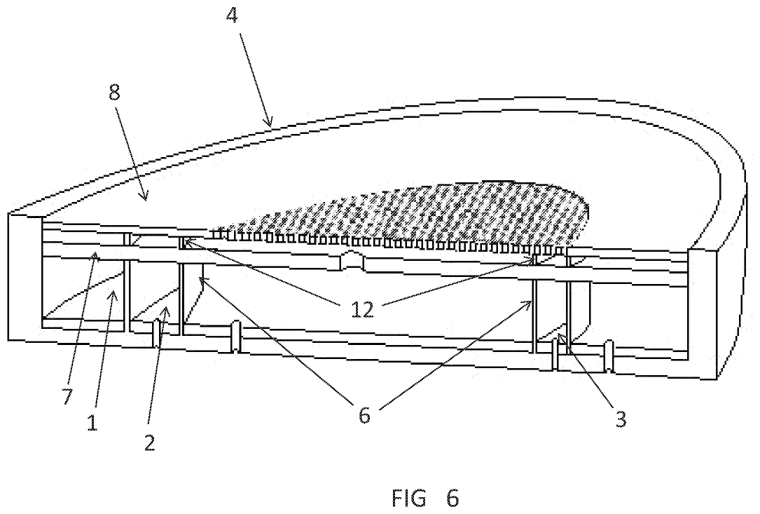

Referring to FIG. 6, the plating apparatus in embodiment 5 includes all the components of the plating apparatus in the embodiment 3, which will not be repeated here.

What's more, a diffusion plate 8 is set in the cathode area of the plating chamber 4, and there are several perforations with the same size or different sizes on the diffusion plate 8 to control the flow field and electric field in the plating process. The desired metal ions pass through the ionic membrane 7 and the diffusion plate 8 and reach the wafer then deposit on it.

In the present embodiment, the diffusion plate 8 is detachably mounted on the plating chamber 4, and each plating apparatus can be configured with different types of diffusion plates 8 to match wafers with different sizes or with notches in different shapes. Before plating, install the corresponding diffusion plate 8 according to the actual situation.

The diffusion plate 8 corresponding to an 8-inch (a smaller size) wafer is illustrated in the present embodiment. It can be seen from FIG. 6 that the area with perforations on the diffusion plate 8 is corresponding to the second anode area 3 for an 8-inch wafer, and there is no perforation in the area corresponding to the second anode area 2 for a 12-inch wafer on the diffusion plate 8.

If the 12-inch wafer or a wafer with a notch in other shape needs to be plated, the diffusion plate 8 corresponding to the 8-inch wafer is removed and another matching diffusion plate 8 is mounted on the plating chamber 4.

Certainly, as with the fourth embodiment, a baffle plate 9 can be detachably assembled in the present plating apparatus. After the diffusion plate 8 corresponding to the 12-inch wafer is mounted, the baffle plate 9 is employed to cover the periphery annular region of the diffusion plate 8, so that only the central area of the diffusion plate 8 is exposed to fit for the plating of the 8-inch wafer.

### Embodiment 6

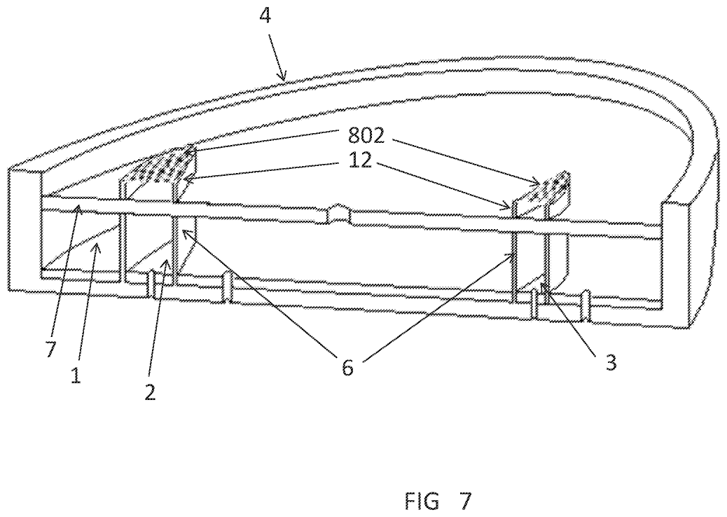

Referring to FIG. 7, the plating apparatus in the sixth embodiment includes all the components of the plating apparatus in the third embodiment, which will not be repeated here.

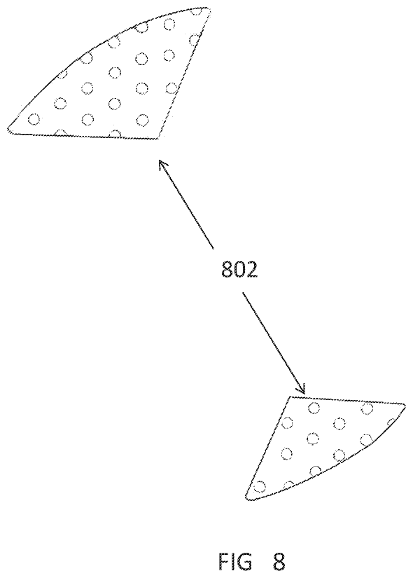

What's more, there are two second diffusion plates 802 respectively assembled on the top of the two second bounding walls 12, and each second diffusion plate 802 has a second perforations-area. The shape of the two second diffusion plates 802 is shown in FIG. 8.

A main diffusion plate 801 is detachably mounted in the cathode area. The location of the main diffusion plate 801 is corresponding to the main anode area, and there is a main perforations-area on the main diffusion plate 801.

Each plating apparatus is configured with two types of main diffusion plates 801 which are respectively used for the plating of the 12-inch wafer and the 8-inch wafer.

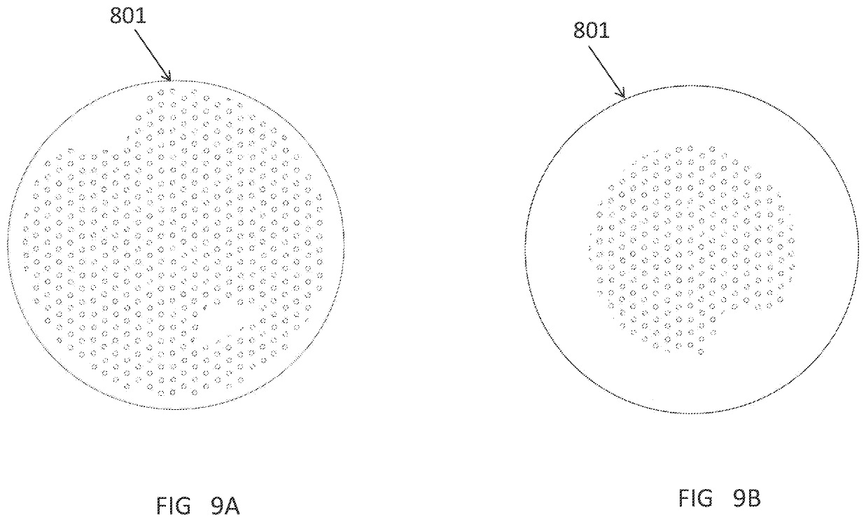

Referring to FIG. 9A, there are two notch areas on the first type of main diffusion plate 801, and each notch area is corresponding to one second diffusion plate 802. After the main diffusion plate 801 is mounted, the two second diffusion plates 802 are respectively assembled on the two notch areas of the main diffusion plate 801. The main perforations-area of the main diffusion plate 801 and the two second perforations-areas of the two second diffusion plates 802 join together to form a complete circle, which is used for the plating of the 12-inch wafer.

Referring to FIG. 9B, there is a notch area on the second type of main diffusion plate 801, and the notch area is corresponding to one second diffusion plate 802. After the main diffusion plate 801 is mounted, the second diffusion plate 802 is assembled on the notch area of the main diffusion plate 801. The main perforations-area of the main diffusion plate 801 and the second perforations-area of the second diffusion plate 802 join together to form a complete circle, which is used for the plating of the 8-inch wafer.

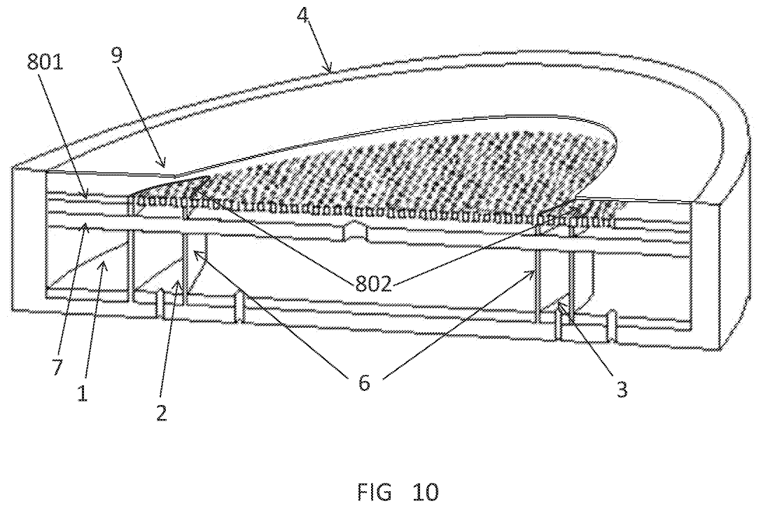

Certainly, as with the fourth embodiment, the first type of main diffusion plate 801 can be fixed in the cathode area. Referring to FIG. 10, if the 8-inch wafer needs to be plated, the baffle plate 9 is employed to cover the periphery annular region of the entire circle consisting of the main perforations-area of the main diffusion plate 801 and the two second perforations-areas of the two second diffusion plate 802, and the uncovered area is fit for the plating of the 8-inch wafer. The baffle plate 9 is detachably mounted on the plating chamber 4 or the main diffusion plate 801.

The second diffusion plate 802 can be designed and replaced based on the need of the process. For example, the density and diameter of the perforations in the second perforations-area of the second diffusion plate 802 can be designed based on the need of the process.

In order to reduce the total electric quantity received by the notch area of the wafer in the second anode area, the density of the perforations in the second perforations-area of the second diffusion plate 802 is smaller than that of the main diffusion plate 801, and/or the diameter of the perforations in the second perforations-area of the second diffusion plate 802 is smaller than that of the main diffusion plate 801, so that the height of the plating metal near the notch area of the wafer is further controlled. What is more, the density and diameter of the perforations in the second perforations-area can be adjusted separately to fit for different products, because the non-plated areas at notches of different wafers are different.

### Embodiment 7

The difference between the present embodiment and the first embodiment is that, referring to FIG. 12, in the plating apparatus in the seventh embodiment, the second anode area 3 for an 8-inch wafer and the second anode area 2 for a 12-inch wafer are separately connected to an independent second power supply 11 and the main anode area 1 is connected to the main power supply 10. The negative poles of the main power supply 10 and the two second power supplies 11 are connected to the wafer 14 via the wafer chuck 13. In the plating process of the 12-inch wafer, the main anode area 1, the second anode area 3 for an 8-inch wafer and the second anode area 2 for a 12-inch wafer are controlled separately. Because the second anode area 3 for an 8-inch wafer is closer to the center area of the 12-inch wafer, and the second anode area 2 for a 12-inch wafer is corresponding to the periphery area of the 12-inch wafer, the central area and the periphery area of the 12-inch wafer can be controlled separately, which is more flexible.

Other parts are the same with the embodiment 1.

### Embodiment 8

The difference between the present embodiment and the first embodiment is that, in the plating apparatus in the present embodiment, the through hole 5 acts as a switch interface that can be used to connect each electrode to a multi-way switch circuit, and then the multi-way switch circuit is connected to different power supplies or other control units.

Other parts are the same with the embodiment 1.

From the first embodiment 1 to the eighth embodiment 8, the main anode area 1, the second anode area 3 for an 8-inch wafer and the second anode area 2 for a 12-inch wafer respectively have their own independent anode electrolyte supply branch, and each branch is equipped with a needle valve. The flow rate in each area can be controlled by adjusting the opening degree of the needle valve, and the flow field corresponding to the area can be supplemented or reduced by increasing or decreasing the flow rate, combined with the electric field intensity to control the height of the plating metal in each area.

The plating apparatuses from the first embodiment 1 to the eighth embodiment 8 are fit for wafers with other sizes but not limited to 8-inch and 12-inch. The shape of the second anode area can be a circular sector, an arc and an arch, etc., which is corresponding to the shape of the notch of the wafer.

### Embodiment 9

A plating method is disclosed in the ninth embodiment. The method comprises: plating on the surface of a wafer with a plating apparatus having electrodes, and the electrodes comprise a main electrode and at least two second electrodes; controlling each electrode to generate an electric field in the corresponding area on the surface of the wafer, and each second electrode and the main electrode being controlled independently or controlled jointly; by changing the combination of the control relationship between each second electrode and the main electrode, wafers with different sizes or different notch shapes are plated.

According to an optional way, by connecting the main electrode to the main power supply 10 and selectively connecting the second electrode to the main power supply 10 or the second power supply 11, the independent control or joint control between each second electrode and the main electrode is realized. When the second electrode and the main electrode are controlled independently, the electric field intensity generated by the second electrode in the corresponding area is different from the electric field intensity generated by the main electrode in the corresponding area. When the second electrode and the main electrode are controlled jointly, the electric field intensity generated by the second electrode in the corresponding area is the same with the electric field intensity generated by the main electrode in the corresponding area.

According to another optional way, by connecting the main electrode to a main rectifier and selectively connecting the second electrode to the main rectifier or a second rectifier, the independent control or joint control between each second electrode and the main electrode is realized. When the second electrode and the main electrode are controlled independently, the electric field intensity generated by the second electrode in the corresponding area is different from the electric field intensity generated by the main electrode in the corresponding area. When the second electrode and the main electrode are controlled jointly, the electric field intensity generated by the second electrode in the corresponding area is the same with the electric field intensity generated by the main electrode in the corresponding area. The electric field intensity can be changed by adjusting the electric current, the voltage or the duty cycle.

As described above, the foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

1. A plating apparatus, comprising multiple electrodes, the multiple electrodes including a main electrode and at least two second electrodes, the main electrode and the at least two second electrodes respectively generating an electric field in a corresponding area on the surface of a wafer, the main electrode and the at least two second electrodes respectively having a control interface, by selecting the combination of the control relationship between each second electrode and the main electrode, wafers with different sizes or different notch shapes are plated, and the control relationship is independent control or joint control.

2. The plating apparatus as claimed in claim 1, wherein the control interfaces are power interfaces, the main electrode is connected to a main power supply, and each second electrode is selectively connected to a second power supply or the main power supply.

3. The plating apparatus as claimed in claim 1, wherein when the second electrode and the main electrode are controlled independently, the electric field intensity generated by the second electrode in the corresponding area is different from the electric field intensity generated by the main electrode in the corresponding area, when the second electrode and the main electrode are controlled jointly, the electric field intensity generated by the second electrode in the corresponding area is the same with the electric field intensity generated by the main electrode in the corresponding area.

4. The plating apparatus as claimed in claim 1, wherein the main electrode is corresponding to the central area of the wafer, and the electric field generated by each second electrode doesn't overlap with each other.

5. The plating apparatus as claimed in claim 1, wherein the number of the second electrodes is two, and the angle between the axis of one second electrode and the axis of the other second electrode is 180°.

6. The plating apparatus as claimed in claim 1, wherein each second electrode is corresponding to a notch area of the wafer, and the distance between the center of the main electrode and the second electrode corresponding to the notch of a wafer with a larger size is a longer distance, the distance between the center of the main electrode and the second electrode corresponding to the notch of a wafer with a smaller size is a shorter distance, the longer distance is larger than the shorter distance.

7. The plating apparatus as claimed in claim 1, wherein each second electrode is set in a first bounding wall and the first bounding wall is used to separate the electric field generated by the second electrode with the electric field generated by the main electrode.

8. The plating apparatus as claimed in claim 7, further comprising an ionic membrane set on an ionic membrane frame, wherein the ionic membrane is used to separate a cathode area from an anode area in a plating chamber, and the end of the first bounding wall is connected to the ionic membrane.

9. The plating apparatus as claimed in claim 8, further comprising a diffusion plate with a perforations-area matching with the size of the wafer to be plated being set between the ionic membrane and the wafer, multiple perforations being set in the perforations-area, a second bounding wall being set between the ionic membrane and the diffusion plate, the two ends of the second bounding wall being respectively connected to the ionic membrane frame and the diffusion plate, the shape and location of the second bounding wall matching with the shape and location of the first bounding wall.

10. The plating apparatus as claimed in claim 9, wherein the diffusion plate is assembled detachably.

11. The plating apparatus as claimed in claim 8, further comprising a main diffusion plate with a main perforations-area being set between the ionic membrane and the wafer, at least one notch area being set in the main perforations-area, the shape and location of the at least one notch area matching with at least one second electrode, a second bounding wall being set on the ionic membrane frame, the shape and location of the second bounding wall matching with the shape and location of the first bounding wall, a second diffusion plate with a second perforations-area being set on an end of the second bounding wall, multiple perforations being respectively set in the main perforations-area and the second perforations-area, after the main diffusion plate is mounted, the second diffusion plate is correspondingly mounted at the notch area of the main diffusion plate, and the main perforations-area of the main diffusion plate and the second perforations-area of the second diffusion plate join together to form a complete circle.

12. The plating apparatus as claimed in claim 11, wherein the main diffusion plate and the second diffusion plate are mounted detachably.

13. The plating apparatus as claimed in claim 9, further comprising a baffle plate being detachably mounted between the diffusion plate and the wafer, the baffle plate being employed to cover the periphery annular region of the perforations-area in order to fit for the plating of wafers with different sizes.

14. The plating apparatus as claimed in claim 11, wherein the density of the perforations in the second perforations-area is smaller than the density of the perforations in the main perforations-area, and/or the diameter of the perforations in the second perforations-area is smaller than the diameter of the perforations in the main perforations-area.

15. A plating method, comprising:
plating on the surface of a wafer with a plating apparatus having electrodes, wherein the electrodes include a main electrode and at least two second electrodes;
controlling the main electrode and the at least two second electrodes to generate an electric field in the corresponding area on the surface of the wafer, each second electrode and the main electrode being controlled independently or controlled jointly, by changing the combination of the control relationship between each second electrode and the main electrode, wafers with different sizes or different notch shapes being plated.

16. The plating method as claimed in claim 15, further comprising connecting the main electrode to a main power supply and selectively connecting each second electrode to a second power supply or the main power supply so that the independent control or joint control between each second electrode and the main electrode is realized.

17. The plating method as claimed in claim 15, wherein when the second electrode and the main electrode are controlled independently, the electric field intensity generated by the second electrode in the corresponding area is different from the electric field intensity generated by the main electrode in the corresponding area, when the second electrode and the main electrode are controlled jointly, the electric field intensity generated by the second electrode in the corresponding area is the same with the electric field intensity generated by the main electrode in the corresponding area.

18. The plating method as claimed in claim 15, further comprising connecting the main electrode to a main rectifier and selectively connecting the second electrode to the main rectifier or a second rectifier so that the independent control or joint control between each second electrode and the main electrode is realized.
